(19) United States
(12) Patent Application Publication
(10) Pub. No.: US 2009/0139448 A1
(43) Pub. Date: Jun. 4, 2009

(54) VAPOR PHASE GROWTH APPARATUS ANS VAPOR PHASE GROWTH METHOD

(76) Inventors: Hironobu HIRATA, Shizuoka (JP); Masayoshi Yajima, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/323,362

(22) Filed: Nov. 25, 2008

(30) Foreign Application Priority Data
Nov. 29, 2007 (JP) 2007-309271

(51) Int. Cl. C30B 23/06

(52) U.S. Cl. 117/107

(57) ABSTRACT

A vapor phase growth apparatus and a vapor phase growth method capable of improving the yield rate of wafers by stopping infiltration of metal contaminants generated below a horizontal disk-like susceptor is provided. The vapor phase growth apparatus according to embodiments of the present invention includes a holder having an annular shape and on which a wafer can be placed, a disk-shaped susceptor on which the holder can be placed and provided on an upper surface thereof with circumferential steps inscribed in inner circumferential edge of the holder when the holder is placed, a rotation driving mechanism for rotating the susceptor and the holder at a predetermined rotational speed, a heating mechanism for heating the wafer placed on the holder, and a wafer push-up mechanism to push up an undersurface of the holder outside the rotation driving mechanism.

### CROSS-REFERENCE TO RELATED APPLICATION

This application is based upon and claims the benefit of priority from Japanese Patent Application No. 2007-309271, filed on Nov. 29, 2007 the entire contents of which are incorporated herein by reference.

### FIELD OF THE INVENTION

The present invention relates to a vapor phase growth apparatus and a vapor phase growth method, and in particular, relates to a vapor phase growth apparatus and a vapor phase growth method capable of preventing infiltration of particulate contaminants, which present a problem to efficiently form a vapor phase growth film, contaminating a silicon wafer (hereinafter, described as Si).

### BACKGROUND OF THE INVENTION

A single-wafer apparatus is known as a kind of vapor phase growth apparatus. This apparatus is used to form an epitaxial vapor phase growth film on the upper surface of a wafer by placing the wafer on a horizontal disk-like susceptor arranged inside a heat treat furnace and allowing a material gas and a carrier gas to flow over the wafer inside the furnace while rotating the susceptor around a vertical axis. This apparatus is used more frequently with an increasing diameter of the wafer and is viewed as mainstream also in a 300-mm wafer compliant apparatus. Such apparatuses are well known to manufacture silicon epitaxial wafers by allowing vapor phase growth of a silicon epitaxial layer on a main surface of a single crystal silicon substrate.

The vapor phase growth apparatus has a susceptor provided inside a chamber to be a reaction chamber and the susceptor is disposed rotatably around a rotation axis with countersunk formed at outer circumferential surface of the susceptor to place a wafer. A heating means is provided below the susceptor. In order to manufacture silicon epitaxial wafers by a vapor phase growth apparatus using such a horizontal disk-like susceptor, a reaction gas is fed together with a carrier gas into the chamber heated to a predetermined temperature by the heating means from a gas feed pipe. The reaction gas is fed over the single crystal silicon substrate flowing along the susceptor being rotated around the rotation axis before being discharged out of a gas exhaust pipe.

Incidentally, the silicon material gas used in the reaction is generally silicon tetrachloride (SiCl₄) or trichlorsilane (SiHCl₃), and a hydrogen chloride (HCl) gas is used before the reaction to etch the single crystal silicon substrate. The HCl gas is also used for cleaning to etch reaction by-products adhering to inner walls of the chamber or gas pipe.

These gases are corrosive and particularly when moisture adheres, hydrochloric acid is formed, which is known to rapidly corrode various kinds of metal. Therefore, a technology to use silicon carbide (SiC) or quartz (SiO₂) having properties resistant to chlorine-based substance for the chamber that seals the whole apparatus and the susceptor more likely to come into contact with wafers is disclosed by JP-A 2001-274094 (KOKAI).

### SUMMARY OF THE INVENTION

However, according to the technology disclosed by JP-A 2001-274094 (KOKAI), while the chamber, susceptor and peripheral components thereof are less likely to be corroded by such gases because silicon carbide (SiC) or quartz (SiO₂) is used, stainless steel usually forms the rotary drum and the like in terms of strength and may be corroded by passage of the high-temperature corrosive gas. Moreover, the chamber is temporarily exposed to the atmosphere during, for example, maintenance. On that occasion, the atmosphere enters the chamber and as a result of a considerable amount of moisture contained in the atmosphere and the corrosive gas, though very small quantities, remaining in metallic components such as the rotary drum being mixed, hydrochloric acid is formed to corrode metallic components.

Corrosion products generated on metal by the corrosion easily react with the corrosive gas to generate a gaseous chloride compound. Then, since the gaseous chloride compound has high vapor pressure, the gaseous chloride compound diffuses from metallic components into the chamber before being incorporated into a silicon wafer generated in the chamber. As a result, deterioration of quality such as the carrier lifetime of silicon wafers being deteriorated may be caused. Generation of such metal contaminants is a major problem causing deterioration of the yield rate of wafers.

The present invention has been made in view of the above subject and an object thereof is to provide a vapor phase growth apparatus and a vapor phase growth method capable of improving the yield rate of wafers by stopping infiltration of metal contaminants generated below a susceptor in an apparatus provided with the horizontal disc-like susceptor to form a vapor phase growth film by heating to a high temperature while rotating the susceptor at high speed.

A vapor phase growth apparatus according to an embodiment of the present invention includes a holder having an annular shape and on which a wafer can be placed, a disk-shaped susceptor on which the holder can be placed and provided on an upper surface thereof with circumferential steps inscribed in inner circumferential edge of the holder when the holder is placed, a rotation driving mechanism for rotating the susceptor and the holder placed on the susceptor at a predetermined rotational speed, a heating mechanism for heating the wafer placed on the holder, and a wafer push-up mechanism to push up an undersurface of the holder outside the rotation driving mechanism.

A vapor phase growth method according to an embodiment of the present invention using a vapor phase growth apparatus including a holder having an annular shape and on which a wafer can be placed, a disk-shaped susceptor on which the holder can be placed and provided on an upper surface thereof with circumferential steps inscribed in inner circumferential edge of the holder when the holder is placed, a rotation driving mechanism for rotating the susceptor and the holder placed on the susceptor at a predetermined rotational speed, a heating mechanism for heating the wafer placed on the holder, and a wafer push-up mechanism to push up an undersurface of the holder outside the rotation driving mechanism includes elevating the wafer push-up mechanism to push up the holder placed on the susceptor, carrying in the wafer to place the wafer on the holder, lowering the wafer push-up mechanism to place the holder on the susceptor, rotating the wafer by the rotation driving mechanism and heating the wafer by the heating mechanism to form a vapor phase growth film on the wafer, elevating the wafer push-up mechanism to push up the holder placed on the susceptor, and carrying out the wafer.

According to the present invention, an effect of providing a vapor phase growth apparatus and a vapor phase growth method capable of improving the yield rate of wafers by stopping infiltration of metal contaminants from below a wafer by a susceptor positioned always below the wafer and having no opening by providing a horizontal disk-like susceptor provided with circumferential steps on an upper surface thereof and an annular-shaped holder having approximately the same inner circumferential diameter as a circumferential diameter of the circumferential steps to support the susceptor, holder, and wafer from below in this order, to push up an undersurface of a projection part of the holder when the wafer is replaced, and to push up the wafer and holder is achieved.

### BRIEF DESCRIPTION OF THE DRAWINGS

FIG. 1 is a sectional view showing an outline configuration of a vapor phase growth apparatus in the present embodiment.

FIG. 2 is a top view in an E-E direction in FIG. 1 of the vapor phase growth apparatus in the present embodiment.

FIG. 3A and FIG. 3B are top views showing other forms of a projection part of the vapor phase growth apparatus in the present embodiment.

FIG. 4 is a top view showing an inserted state of a wafer transport arm in the vapor phase growth apparatus in the present embodiment.

FIG. 5 is an enlarged sectional view showing a placement state of a wafer in the vapor phase growth apparatus in the present embodiment.

FIG. 6A to FIG. 6D are diagrams showing shape examples of a wafer push-up mechanism in the present embodiment.

FIG. 7 is an enlarged sectional view showing a pushed-up state of a holder of the vapor phase growth apparatus in the present embodiment.

FIG. 8 is a block diagram showing an outline configuration of a single wafer multi-chamber 20 of vapor phase growth apparatuses in the present embodiment.

### DETAILED DESCRIPTION OF THE EMBODIMENTS

An embodiment of a vapor phase growth apparatus and a vapor phase growth method according to the present invention will be described below based on appended drawings.

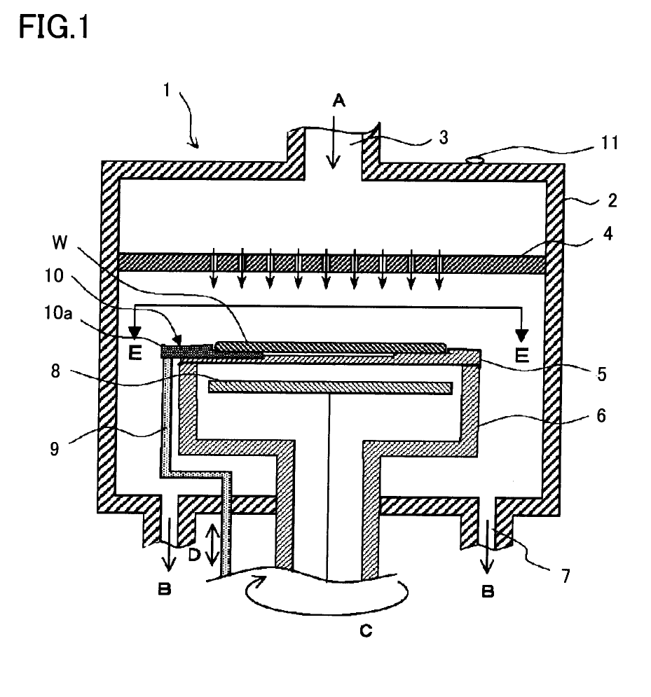

A vapor phase growth apparatus according to the present embodiment will be described in detail below. FIG. 1 is a sectional view showing an outline configuration of a vapor phase growth apparatus 1 according to the present embodiment. The vapor phase growth apparatus 1 is, for example, an apparatus for growing high-purity single crystal silicon (hereinafter, referred to as Si) on a Wafer W of Si by the vapor phase growth method, and includes a chamber 2, a gas feed pipe 3 connected to the chamber 2 via a pipe, and a gas exhaust pipe 7.

The gas feed pipe 3 is disposed in an upper part inside the chamber 2 and substantially a central part in the horizontal direction and is connected to a gas feed control device (not shown) outside the chamber 2 so that a material gas, carrier gas, or dopant gas is fed into the chamber 2. A material gas, carrier gas, or dopant gas is fed in an A direction in FIG. 1 depending on the type of the vapor phase growth film to be formed in the vapor phase growth apparatus 1. The material gas to be suitably selected and used includes, in addition to silicon tetrachloride (SiCl₄), dichlorsilane (SiH₂Cl₂), trichlorsilane (SiHCl₃), and silane (SiH₄). Hydrogen (H₂) is used as the carrier gas. The dopant gas to be suitably selected and used includes phosphine (PH₃), diborane (B₂H₆), and arsenic (As) compounds.

The gas exhaust pipe 7 is disposed at two separate locations on the left and right sides in FIG. 1, at the lower part of the chamber 2, to exhaust hydrogen chloride (hereinafter, referred to as HCl) generated as a result of reaction of a silicon material gas and a carrier gas H₂ inside the chamber 2, and a carrier gas, material gas, and dopant gas that did not react. The gas exhaust pipe 7 is connected to a gas exhaust control device (not shown) outside the chamber 2 so that these gases are exhausted out of the chamber 2. With the gas exhaust control device (not shown) being connected, a gas exhausted in a B direction in FIG. 1 is disposed of.

Further, the chamber 2 includes a straightening vane 4, a susceptor 5, a holder 10, a rotary drum 6, a heater 8, a wafer push-up mechanism 9, and a temperature sensor 11 therein. A wafer W may be placed on the holder 10

The straightening vane 4 is a member to cause the material gas, carrier gas, and dopant gas after being fed from the gas feed pipe 3 to uniformly flow in over the wafer W, is formed from quartz or the like, and is fixed to the inner wall surface of the chamber 2 between the gas feed pipe 3 and the susceptor 5. The straightening vane 4 has a large number of openings provided over a whole region opposite to the wafer W and the area of openings is adjusted so that a uniform gas flow rate is generated over the whole region of the wafer W.

A radiation thermometer or the like is used as the temperature sensor 11 to remotely detect the surface temperature of a wafer from a transparent quartz window provided in the outer wall of the chamber 2. The heater 8 is a heater to heat the wafer W until a process temperature of vapor phase growth is reached from the rear side and is heated by a constant current supplied from a heating circuit (not shown) provided outside the chamber 2, according to the sensed temperature of the temperature sensor 11. The process temperature depends on the material gas and ranges from 900° C. to 1250° C.

The wafer W is a high-purity single crystal Si to be formed as a vapor phase growth film. To form a vapor phase growth film on the wafer W, the wafer W is heated up to the process temperature by the heater 8. The wafer W is normally a wafer obtained by slicing a silicon ingot after being fabricated by the FZ method or CZ method and performing wrapping treatment or etching treatment.

The holder 10 has an annular shape to support the wafer W on which a vapor phase growth film is formed in a predetermined position and accommodates the wafer W on circumferential steps in the annular shape. The holder 10 also has projection parts 10a at three locations in an edge part of the holder 10. Therefore, when the wafer W is replaced, the holder 10 is pushed up while supporting the wafer W by the projection parts 10a being pushed up. The material of the holder 10 is preferably a carbon substrate coated with silicon carbide (hereinafter, referred to as SiC), a SiC substrate, or silicon impregnated silicon carbide from the viewpoint of the heat conductivity, thermal expansibility, heat resistance, high-purity manufacturability, and the like.

The susceptor 5 has functions to support the holder 10 in a predetermined position and also to stop infiltration of particulate contaminants from below the susceptor 5 to prevent contamination of the wafer W. Therefore, the susceptor 5 is required to have a substantially disk shape having no opening in the vertical direction to the wafer W. That is, the susceptor 5 is required to have no opening on the upper surface thereof. Like the holder 10, the material of the susceptor 5 is preferably a carbon substrate coated with silicon carbide (hereinafter, referred to as SiC), a SiC substrate, or silicon impregnated silicon carbide.

The rotary drum 6 is a rotator to rotate the susceptor 5 and has a drive function to rotate the wafer W at a high constant rotational speed in a C direction in FIG. 1 so that a vapor phase growth film on the wafer W is generated uniformly. In order to form a highly uniform vapor phase growth film efficiently when a vapor phase growth apparatus according to the present embodiment is practically used, the rotational speed is preferably 500 rpm or more when a vapor phase growth film is formed.

The wafer push-up mechanism 9 has a function to push up the wafer W together with the holder 10 from below. The wafer push-up mechanism 9 is disposed outside the rotary drum 6 and reciprocated vertically in a D direction in FIG. 1 by a drive mechanism (not shown) provided outside. The wafer push-up mechanism 9 is constructed in such that when a pin operates upward, the pin pushes up the projection part 10a of the holder 10 so that the holder 10 is pushed up while the wafer W being placed thereon.

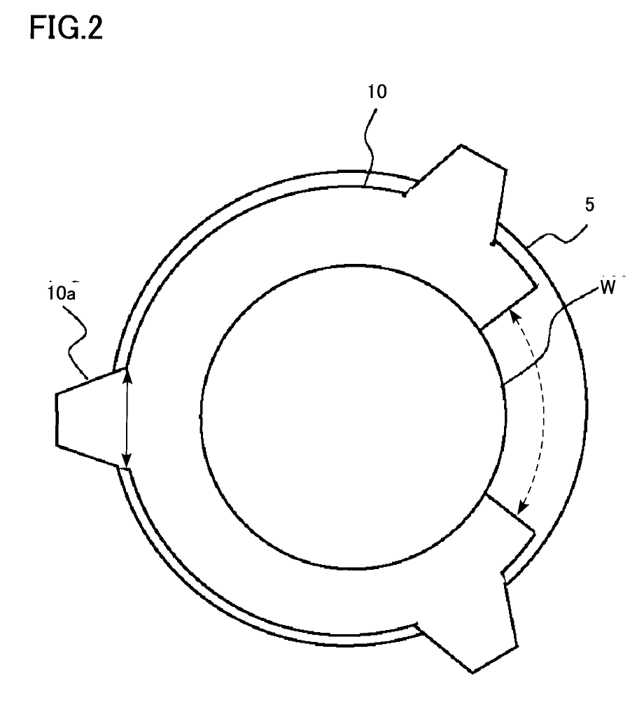

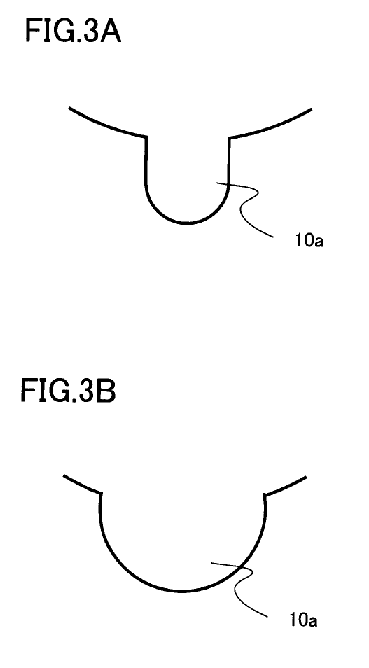

Spatial relationships among the wafer W, the holder 10, and the susceptor 5 will be described below in detail. FIG. 2 is a top view in an E-E direction in FIG. 1 of the vapor phase growth apparatus 1 according to the present embodiment. In FIG. 2, the susceptor 5 supports the holder 10 and the holder 10 supports the wafer W. The holder 10 has the projection part 10a at three locations like projecting from an outer circumferential diameter of the susceptor 5. The projection part 10a provided in the edge part of the holder 10 shows in FIG. 2 a substantially trapezoidal shape. The length (solid line double arrow in FIG. 2) of the base of the trapezoid is preferably 5 to 20 mm. However, the projection part 10a may also have a round shape at the tip part, as shown in FIG. 3A, or a substantially circular shape, as shown in FIG. 3B, or a substantially rectangular shape. The projection part 10a preferably has a minimum area when the pin of the wafer push-up mechanism 9 comes into contact. With an increasing area of the projection part 10a, the weight of the holder 10 increases and thus, sufficient driving torque for the wafer push-up mechanism 9 to push up the holder 10 is needed.

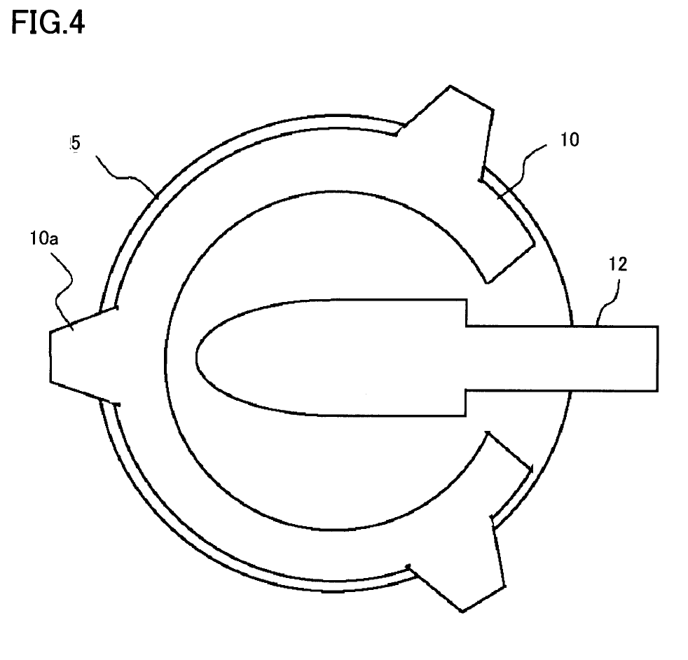

A state of a wafer transport arm 12 when the wafer W is transported will be described in detail. FIG. 4 is a top view showing an inserted state of the wafer transport arm 12 in a vapor phase growth apparatus according to the present embodiment. As shown in FIG. 4, the wafer transport arm 12 has an elongated shape and the shape at the tip of the arm is not limited. The wafer transport arm 12 carries in or caries out the wafer W by an insertion operation into an opening of the holder 10 or a withdrawing operation from the opening. The holder 10 has an annular shape a portion thereof is open. The opening is provided so that the wafer transport arm 12 is inserted. The annular-shaped portion of the holder 10 has the projection part 10a provided at three locations and thus, has a shape extending over 240 degrees. Moreover, as shown in FIG. 1, the susceptor 5 includes convex steps and supports the wafer W in a region where a portion of the annular shape of the holder 10 is open.

An operation of the wafer push-up mechanism 9 will be described below in detail. FIG. 5 is an enlarged sectional view showing a wafer W placed state of in a vapor phase growth apparatus according to the present embodiment. The susceptor 5 is supported by the rotary drum 6. In this state, the wafer W is supported inside the inner circumferential step of the annular-shaped holder 10 and the annular-shaped holder 10 is supported by the inner circumferential edge thereof being in contact with a circumferential step provided on the upper surface of the susceptor 5. Also, a pin tip of the wafer push-up mechanism 9 is in contact with an undersurface of the projection part 10a of the holder 10 or at a position to immediately come into contact therewith. While the wafer W is being supported inside the annular-shaped inner circumferential step of the annular-shaped holder 10, it is preferable to provide a space of several hundred μm to 1 mm between the undersurface of the wafer W and the upper surface of the susceptor 5.

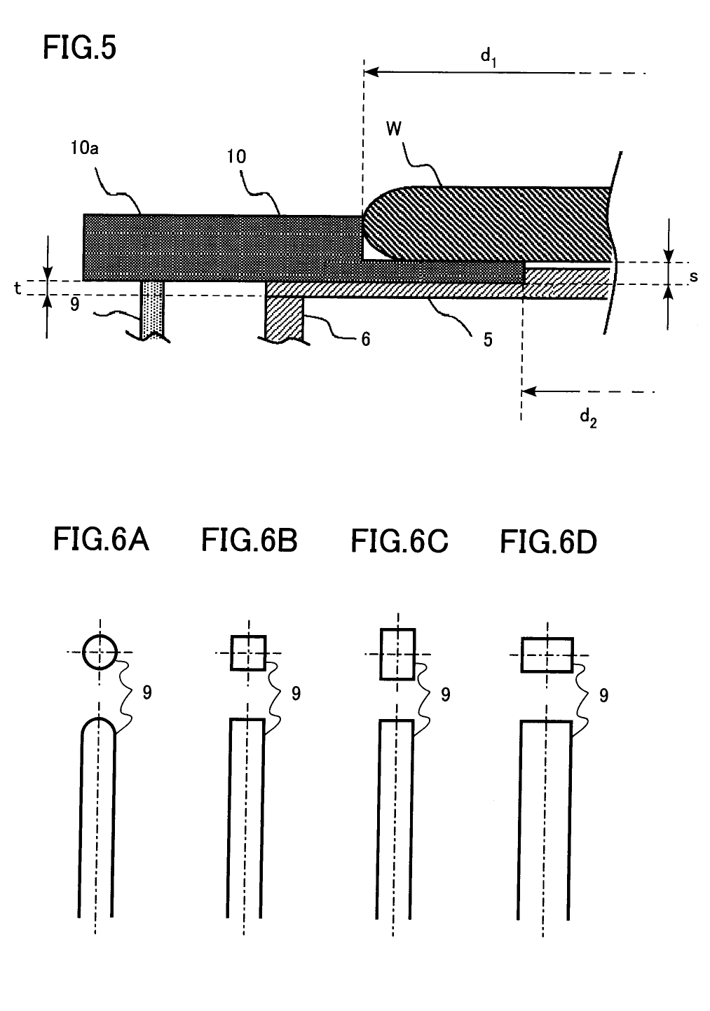

In FIG. 5, when the pin of the wafer push-up mechanism 9 performs a push-up operation, the pin pushes up the undersurface of the projection part 10a of the holder 10. FIG. 6A to FIG. 6D are diagrams showing examples of the shape of the wafer push-up mechanism. Upper figures are top views and lower figures are sectional views. As shown in these figures, various shapes can be adopted for the pin of the wafer push-up mechanism.

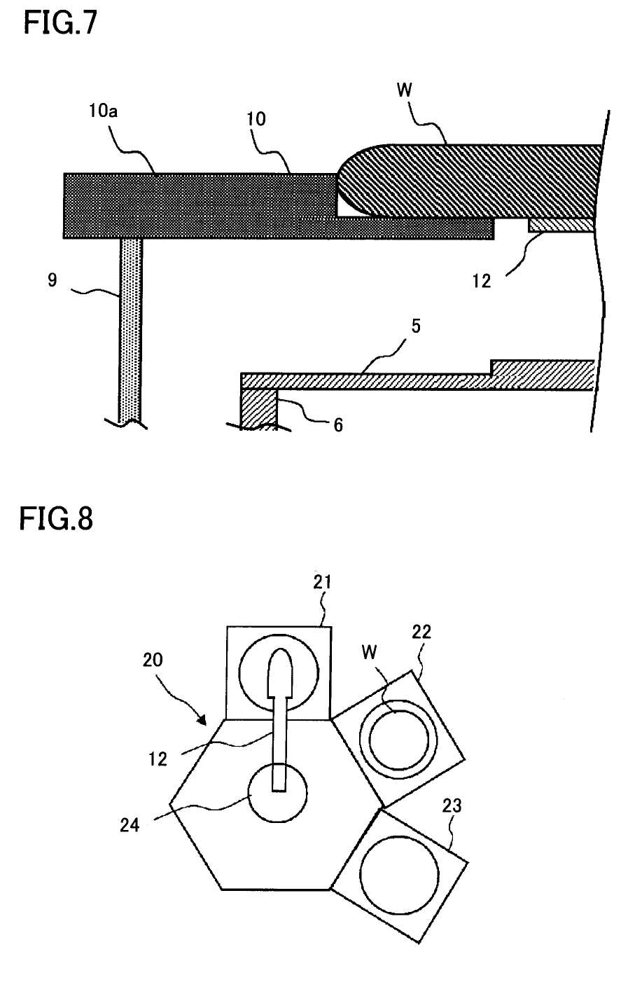

FIG. 7 is an enlarged sectional view showing a pushed-up state of the holder 10 of a vapor phase growth apparatus according to the present embodiment. FIG. 7 shows a state in which the holder 10 is pushed up while the wafer W being supported after the pin of the wafer push-up mechanism 9 being pushed up. As shown in FIG. 7, while the holder 10 is pushed up, the wafer transport arm 12 is inserted below the wafer W. Subsequently, the pin of the wafer push-up mechanism 9 descends and the wafer transport arm 12 supporting the wafer W transports the wafer W to another chamber or the next process.

By stopping infiltration of metal contaminants generated from the heater 8 or the rotary drum 6 positioned below the susceptor 5 into the vicinity of the wafer W, as described above, a semiconductor manufacturing method to improve the yield rate of wafers can be realized in a system of multi-chamber configuration in which a wafer transport robot is connected to a plurality of vapor phase growth apparatuses. FIG. 8 is a block diagram showing an outline configuration of the single wafer multi-chamber 20 of vapor phase growth apparatuses according to the present embodiment. In FIG. 8, the single wafer multi-chamber 20 includes vapor phase growth apparatuses 21, 22, and 23 using a susceptor accommodating one wafer W to form a vapor phase growth film, the wafer transport arm 12, and a wafer transport robot 24.

The vapor phase growth apparatuses 21, 22, and 23 are apparatuses for accommodating a single wafer and forming a vapor phase growth film on the wafer, as described above, and the type of the material gas, carrier gas, and dopant gas and that of wafer are selected suitably in accordance with an objective thereof. The wafer transport robot 24 can carry a wafer into any of the vapor phase growth apparatuses 21, 22, and 23 or carry a wafer out of any of the vapor phase growth apparatuses 21, 22, and 23 by operating the wafer transport arm 12.

According to the present embodiment, as described above, a vapor phase growth apparatus and a vapor phase growth method capable of improving the yield rate of wafers by stopping infiltration of metal contaminants generated from the heater 8 or the rotary drum 6 positioned below the susceptor 5 into the vicinity of the wafer W also when the wafer W is replaced in a configuration in which the susceptor 5 in a substantially disk shape without opening supports the holder 10 and the holder 10 supports the wafer W by the projection part 10a of the holder 10 being pushed up by the wafer push-up mechanism 9 for replacing the wafer.

In the present embodiment, the projection part 10a provided in the holder 10 is assumed to have a substantially trapezoidal shape to describe an embodiment in detail. However, the present embodiment is not limited to this and the projection part 10a may also have a substantially circular shape or a substantially rectangular shape. It is sufficient for the projection part 10a to have such an area that the holder 10 is pushed up by the pin being pushed up by the wafer push-up mechanism 9.

The present embodiment is described in detail by assuming that the number of pins of the wafer push-up mechanism 9 and the number of locations where the projection part 10a is set up are both three, but if the number of locations is two, there is a danger of the wafer W being damaged due to instability when the holder 10 is pushed up. If, on the other hand, the number of locations is eight or more, the opening angle of the holder 10 will be narrower, which leaves no spatial margin when the wafer transport arm 12 is inserted and increases a danger of interference when the wafer transport arm is inserted. The danger of interference further increases when the wafer transport arm is inserted if the number of locations is five or more. Therefore, the number of locations of the projection part 10a is preferably three or four.

The opening angle (dotted line double arrow in FIG. 2) of the holder 10 needs to be 40 degrees or more in order to avoid a danger of interference when the wafer transport arm is inserted. For a vapor phase growth apparatus processing an 8-inch (200 mm) wafer, a circumcircle of the projection parts of the holder 10 preferably has a diameter of 270 to 290 mm. The distance (s in FIG. 5) between the undersurface of the holder 10 and that of a wafer when the wafer is placed on the holder 10 is preferably 0.5 to 3.0 mm. The diameter (d₁ in FIG. 5) of the inner circumferential step on the upper surface of the holder 10 is preferably a little over 200 mm. The outside diameter (d₂ in FIG. 5) of the circumferential step provided on the upper surface of the susceptor 5 is preferably 160 to 198 mm. Further, the thickness (t in FIG. 5) outside the circumferential step provided on the upper surface of the susceptor 5 is preferably 0.5 to 3.0 mm.

In the present embodiment, an embodiment having a shape in which projection parts are provided in the edge part of the annular-shaped holder is described in detail, but the holder may have a shape without projection parts in which an outer circumferential diameter is larger than that of the susceptor only by an area enough for pins of the wafer push-up mechanism to contact bumps against. In this case, there is an advantage that holder machining will become very easy. However, the weight of the holder increases and thus, the load on the pins of the wafer push-up mechanism becomes heavier and it becomes necessary to increase the strength of pins or increase drive load capacity when the holder is pushed up.

In the present embodiment, an apparatus having a multi-chamber is described in detail, but this invention can also be applied to an apparatus having a single-chamber.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A vapor phase growth apparatus, comprising:
a holder having an annular shape and on which a wafer can be placed;
a disk-shaped susceptor on which the holder can be placed and provided on an upper surface thereof with circumferential steps inscribed in inner circumferential edge of the holder when the holder is placed;
a rotation driving mechanism for rotating the susceptor and the holder placed on the susceptor at a predetermined rotational speed;
a heating mechanism for heating the wafer placed on the holder; and
a wafer push-up mechanism to push up an undersurface of the holder outside the rotation driving mechanism.

2. The apparatus according to claim 1, wherein the holder comprises a projection part in an edge part and the wafer push-up mechanism pushes up the projection part.

3. The apparatus according to claim 1, wherein the susceptor has no opening on the upper surface thereof.

4. The apparatus according to claim 1, wherein the susceptor is formed from one of a carbon substrate coated with silicon carbide (SiC), a silicon carbide (SiC) substrate, and a silicon impregnated silicon carbide substrate.

5. The apparatus according to claim 1, wherein the wafer push-up mechanism has a pin shape pushing up the undersurface of the holder from below.

6. The apparatus according to claim 2, wherein the wafer push-up mechanism has a pin shape pushing up the undersurface of the projection part from below.

7. The apparatus according to claim 2, wherein the holder has the projection part in the annular-shaped edge part extending an angle of 240 degrees or more.

8. The apparatus according to claim 2, wherein the projection part is provided in three locations at equal intervals.

9. A vapor phase growth method using a vapor phase growth apparatus, including:
a holder having an annular shape and on which a wafer can be placed;
a disk-shaped susceptor on which the holder can be placed and provided on an upper surface thereof with circumferential steps inscribed in inner circumferential edge of the holder when the holder is placed;
a rotation driving mechanism for rotating the susceptor and the holder placed on the susceptor at a predetermined rotational speed;
a heating mechanism for heating the wafer placed on the holder; and
a wafer push-up mechanism to push up an undersurface of the holder outside the rotation driving mechanism, comprising:
elevating the wafer push-up mechanism to push up the holder placed on the susceptor;
carrying in the wafer to place the wafer on the holder;
lowering the wafer push-up mechanism to place the holder on the susceptor;
rotating the wafer by the rotation driving mechanism and heating the wafer by the heating mechanism to form a vapor phase growth film on the wafer;
elevating the wafer push-up mechanism to push up the holder placed on the susceptor; and
carrying out the wafer.

10. The method according to claim 9, wherein the holder comprises a projection part in an edge part and the wafer push-up mechanism pushes up the projection part.

11. The method according to claim 9, wherein the susceptor has no opening on the upper surface thereof.

12. The method according to claim 9, wherein the susceptor is formed from one of a carbon substrate coated with silicon carbide (SiC), a silicon carbide (SiC) substrate, and a silicon impregnated silicon carbide substrate.

13. The method according to claim 9, wherein the wafer push-up mechanism has a pin shape pushing up the undersurface of the holder from below.

14. The method according to claim 10, wherein the wafer push-up mechanism has a pin shape pushing up the undersurface of the projection part from below.

15. The method according to claim 9, wherein the holder has the projection part in the annular-shaped edge part extending an angle of 240 degrees or more.

16. The method according to claim 10, wherein the projection part is provided in three locations at equal intervals.
